(19) United States
(12) Patent Application Publication
(10) Pub. No.: US 2008/0258130 A1
(43) Pub. Date: Oct. 23, 2008

(54) Beveled LED Chip with Transparent Substrate

(76) Inventors: Michael J. Bergmann, Chapel Hill, NC (US); David T. Emerson, Chapel Hill, NC (US); Kevin W. Haberern, Cary, NC (US)

Correspondence Address: SUMMA, ALLAN & ADDITON, P.A., 11610 NORTH COMMUNITY HOUSE ROAD, SUITE 200, CHARLOTTE, NC, 28277, US

(21) Appl. No.: 11/738,665

(22) Filed: Apr. 23, 2007

(51) Int. Cl. H01L 33/00

(52) U.S. Cl. 257/13; 257/95; 438/40; 257/E33.006; 257/E33.008

(57) ABSTRACT

A light emitting diode is disclosed that includes a transparent (and potentially low conductivity) silicon carbide substrate, an active structure formed from the Group III nitride material system on the silicon carbide substrate, and respective ohmic contacts on the top side of the diode. The silicon carbide substrate is beveled with respect to the interface between the silicon carbide and the Group III nitride.

### BACKGROUND

The present invention relates to improvements in light emitting diodes (LEDs), particularly LEDs that emit in the higher energy, higher frequency, shorter wavelength portions of the visible spectrum and that are used in conjunction with a phosphor to produce white light.

Light emitting diodes are one type of photonic semiconductor device. In particular, LEDs emit light in response to a forward current passed across a p-n junction (or functionally equivalent structure) that generates recombinations between electrons and holes. In accordance with well-established quantum principles, the recombination emits energy in discrete amounts and, when the energy is released as a photon, the wavelength (and thus frequency and color) of the photon are characteristic of the semiconductor material forming the diode.

As an additional advantage, because LEDs are solid-state devices, they share the desirable properties of many other semiconductor devices such as long life, relatively robust physical characteristics, high reliability, light weight, and (in many circumstances) low cost.

Chapters 12-14 of Sze, PHYSICS OF SEMICONDUCTOR DEVICES, (2d Ed. 1981) and Chapter 7 of Sze, MODERN SEMICONDUCTOR DEVICE PHYSICS (1998) give a good explanation of a variety of photonic devices, including LEDs. Schubert, LIGHT EMITTING DIODES (Cambridge Press 2003) is devoted entirely to the topic, and specifically addresses Group III nitride diodes in Chapter 8.

Because the maximum amount of energy that can be generated from the recombination is represented by the energy difference between the valence and conduction bands of the emitting material, the range of wavelengths that can be emitted from an LED is to a great extent determined by the material from which it is formed. Stated differently, the maximum energy available from a recombination is defined by the semiconductor's bandgap, while smaller-energy transitions can be obtained by, for example, compensated doping in the semiconductor material. The energy of the photon can never, however, exceed the equivalent size of the bandgap.

Accordingly, in order to produce the higher energy colors such as green, blue, violet, (and in some cases ultraviolet emissions), the semiconductor material used in the LED must have a relatively large bandgap. As a result, materials such as silicon carbide (SiC) and the Group III nitride material system are of significant interest in producing such diodes. In turn, because the Group III nitride materials are “direct” emitters (all of the energy is emitted as the photon), Group III nitride-based diodes are the most widely used and commercially available LEDs for producing blue light. By comparison, in an indirect emitter such as silicon carbide, some of the energy is emitted as a photon and some as vibrational energy.

Although obtaining blue light from semiconductor diodes has interest in its own right, a potentially greater interest exists in the capacity of blue light to be used to produce white light. In some cases a blue emitting LED can be combined with red and green LEDs (or other sources) to produce white light. In a more common application, a blue LED is combined with a phosphor to produce white light. The phosphor is a fluorescent material, usually a mineral that emits a different frequency of light in response to excitation by the blue-emitting LED. Yellow is a preferred responsive color for the phosphor because when the blue light from the LED and the yellow emitted by the phosphor are combined, they give a generally satisfactory white light output for many applications.

As a result, a wide variety of white light emitting diodes that are based upon the Group III nitride material system and a phosphor are available for commercial and experimental applications. Depending upon the application, however, certain diode designs have certain disadvantages.

For example, because large single crystals of Group III nitride materials remain commercially unavailable, Group III nitride-based diodes typically include respective p-type and n-type epitaxial layers of Group III nitride material on a crystal substrate of another material. Silicon carbide and sapphire are the two most common materials for such substrates.

Sapphire has the advantage of being highly transparent with good mechanical strength. Sapphire has the disadvantages, however, of relatively poor heat conduction and a relatively inappropriate lattice match with the Group III nitrides. Sapphire also lacks the capacity to be conductively doped and thus sapphire-based devices are typically horizontally oriented; i.e. with both ohmic contacts (anode and cathode) facing in the same direction. This can be disadvantageous in incorporating the diode into some circuits or structures and also tends to increase the physical footprint for any given size of the active area.

In comparison, silicon carbide can be conductively doped and thus can be used as a substrate in vertically-oriented diodes; i.e. those with the respective ohmic contacts on opposite axial ends of the diode. Silicon carbide also has excellent heat conductivity and provides a much better lattice match with Group III nitrides than does sapphire.

Conductively doping silicon carbide, however, reduces its transparency and thus adversely affects the external quantum efficiency of an LED. As brief background, the ratio of photons produced to carriers injected represents the internal quantum efficiency of a diode; i.e., some proportion of the injected carriers will generate transitions that do not produce photons. Additionally, in any LED some of the generated photons are internally absorbed or internally reflected by the diode materials or (if present) by the packaging materials (typically a polymer).

Thus, the term “external quantum efficiency,” or EQE, is used in this context to refer to the proportion of photons that exit the diode (or its package) as visible light. Specifically, external quantum efficiency describes the ratio of emitted light intensity to current flow (e.g., photons out of the device/electrons injected into the active area). Photons can be lost through absorption within the semiconductor material itself; through absorption in the metals, dielectrics or other materials out of which the diode is made; through reflection losses when light passes from the semiconductor to air because of the differences in refractive index; and from the total internal reflection of light at angles greater than the critical angle defined by Snell's law.

In order to maximize the chip's EQE the absorptive losses of the substrate should be minimized. As used herein, the absorptive losses in the substrate are defined as the photons that are emitted by the active region, but are then absorbed in the substrate and thus do not contribute to the EQE. For a perfectly transparent substrate, the absorptive losses as so defined would be reduced to zero. As used herein, the substrate will be considered transparent when the absorptive losses are less than 10% and more preferably less than 5%.

Because diodes that incorporate phosphors for the purpose of producing white light are often intended for illumination purposes, the amount of light that can be produced by the diode at a given drive current becomes an important factor for comparison between and among various diode structures.

When the LED is used in combination with a phosphor, a number of properties can affect the external quantum efficiency. For example, because the phosphor is usually distributed in the polymer packaging material, controlling the amount and geometry of such distribution can affect (positively or negatively) the overall response of the phosphor to the emitted photons and thus affect the external quantum efficiency.

As another factor, light emitting diodes, like other light sources, tend to produce a greater amount of light in certain directions than they do in other directions. For example, many diodes tend to produce the greatest output in a direction perpendicular (normal) to the epitaxial layers that form the junction. Although this can be useful and desirable for some purposes, it can be less desirable when a phosphor is being used to combine with the diode's photons to produce white light.

The degree to which a diode produces output in a given direction other than normal to the junction can be measured using well recognized and well understood instrumentation and can be expressed in terms of a far field pattern that graphically helps illustrate these characteristics.

One method of evaluating the output of the chip is in terms of its radiant flux and its far field pattern. Radiant flux (Rf) is often expressed in milliwatts (mW) at a standard 20 milliamp (mA) drive current.

The far field pattern represents a measurement of radiant flux emitted from the diode as compared to the angle at which the measurement is taken.

The units of measurement reported herein are conventional and well understood. Thus, the luminous flux measurements are photometry units and are measured in lumens. The corresponding, although not identical radiometry measurement is the radiant flux measured in watts. The efficiency is expressed herein as the luminous flux per watt, based upon the current across the diode, most frequently expressed herein in milliamps.

A useful short summary of these and other technical factors relating to light emitting diodes and lamps is set forth in the Labsphere Technical Guide, “The Radiometry of Light Emitting Diodes,” from Labsphere, Inc. North Sutton, N.H.

### SUMMARY

In one aspect the invention is a light emitting diode that includes a transparent (and potentially low conductivity) silicon carbide substrate, an active structure formed from the Group III nitride material system on the silicon carbide substrate, respective ohmic contacts on the top side of the diode; and with the vertical sides of the silicon carbide substrate being perpendicular with respect to the interface between the silicon carbide and the Group III nitride.

In another aspect the invention is a light emitting diode that includes a transparent (and potentially low conductivity) silicon carbide substrate, an active structure formed from the Group III nitride material system on the silicon carbide substrate, respective ohmic contacts on the top side of the diode; and with the silicon carbide substrate being beveled with respect to the interface between the silicon carbide and the Group III nitride.

In another aspect, the invention is an LED lamp. The lamp includes a lead frame, a transparent beveled silicon carbide substrate on the lead frame, an active structure formed from the Group III nitride material system on the silicon carbide substrate opposite from the lead frame, respective ohmic contacts on the top side of the diode, and a polymer lens over the substrate and active structure.

In another aspect, the invention is an LED lamp. The lamp includes a lead frame, a transparent beveled silicon carbide substrate on the lead frame, an active structure formed from the Group III nitride material system on the silicon carbide substrate opposite from the lead frame, respective ohmic contacts on the top side of the diode, a polymer lens over the substrate and active structure, and a phosphor distributed in the polymer lens that is responsive to the light emitted by the active structure and that produces a different color of light in response.

The foregoing and other objects and advantages of the invention and the manner in which the same are accomplished will become clearer based on the followed detailed description taken in conjunction with the accompanying drawings.

### BRIEF DESCRIPTION OF THE DRAWINGS

FIG. 1 is a photograph of a diode according to the invention in a top plan view orientation.

FIG. 2 is a second photograph of a diode according to the invention in a side elevation orientation.

FIG. 3 is a schematic cross-sectional view of a diode according to the present invention.

FIG. 4 is a far field pattern of a sapphire-based light emitting diode.

FIG. 5 is a far field pattern for a light emitting diode according to the present invention.

FIG. 6 is a schematic diagram illustrating the orientation of an LED chip with respect to the measurements plotted in FIGS. 4 and 5.

FIG. 7 is a plot of normalized light extraction efficiency comparing the relative efficiency of two different LED chip architectures.

FIG. 8 is a schematic diagram of an LED lamp that incorporates a diode according to the present invention.

FIG. 9 is a schematic diagram of a display that incorporates diodes according to the present invention.

FIG. 10 is a reproduction of one version of the CIE Chromaticity Diagram

### DETAILED DESCRIPTION

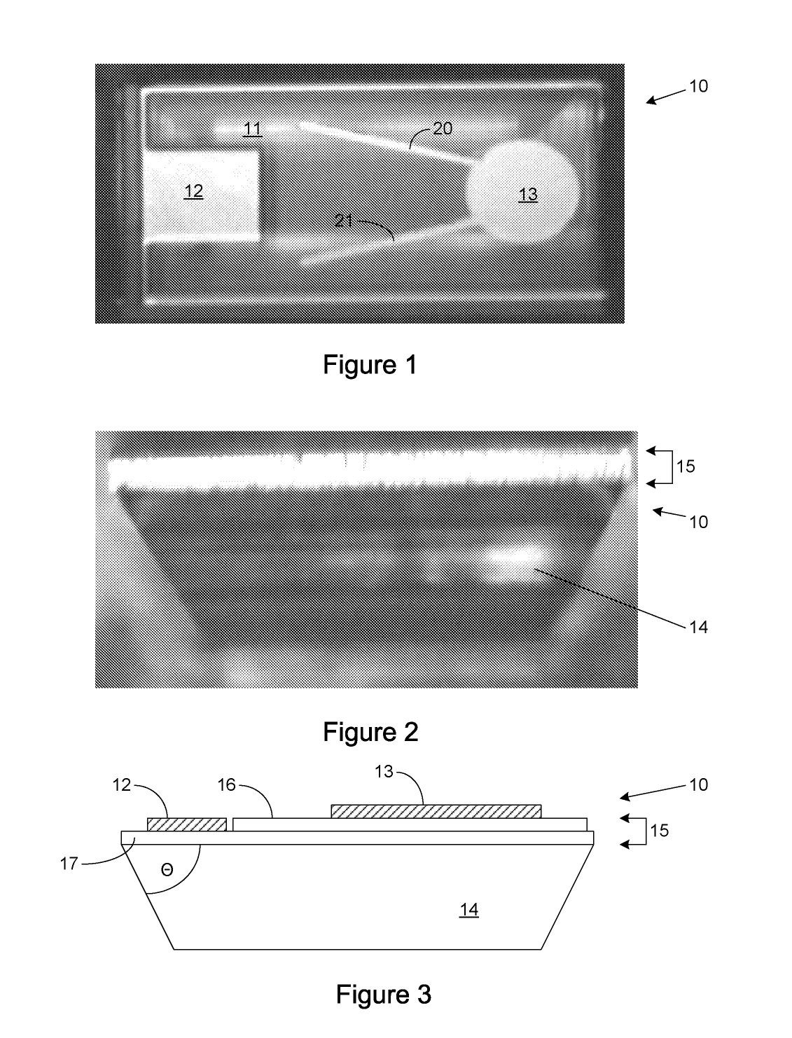

FIG. 1 is a top plan view photograph of a diode according to the invention broadly designated at 10. FIG. 1 illustrates the top surface of the diode 11 which will be typically formed of one of the Group III nitrides. For a number of well-established and well-understood reasons, epitaxial layers are used to form p-n junctions and generate recombinations (and thus photons) in Group III nitride materials. These materials typically include gallium nitride (GaN), aluminum gallium nitride (AlGaN), indium gallium nitride (InGaN) and in some cases indium aluminum gallium nitride (InAlGaN).

The Group III nitride material system is generally well-understood in the diode context. In particular, indium gallium nitride can be a preferred material for one or more of the layers within a diode's active structure because the wavelength of the emitted photons can be controlled to some extent by the atomic fraction of indium in the crystal. This tuning capacity is limited, however, because increasing the amount of indium in the crystal tends to reduce its chemical stability

Other considerations for the material system include crystal stability and lattice matching as well as the ability to withstand various steps, including higher temperature steps, during the fabrication of the diode into a lamp or some other end use. These considerations are likewise well-understood in this art and will not be discussed in detail herein.

FIG. 1 also illustrates the respective ohmic contacts 12 and 13. In the invention, these ohmic contacts both face in the same direction from the diode (and are thus sometimes referred to as “top-side contacts” or “lateral contacts”). Placing the contacts on the same side of the device can reduce the forward voltage of the resulting device by removing the heterointerface from the current path (e.g., the SiC to GaN interface). This lower voltage can be advantageous to some LED applications. Because each respective contact touches a different part of the diode, however (specifically, an n-type portion and a p-type portion respectively), the contacts 12 and 13 may be slightly vertically offset from one another (e.g. FIG. 3). In exemplary embodiments, the ohmic contacts are selected from the group consisting of gold, gold-tin, zinc, gold-zinc, gold-nickel, platinum, nickel, aluminum, indium tin oxide (ITO), chromium, and combinations thereof.

By placing both of the contacts 12 and 13 on Group III nitride layers, the invention can reduce the forward voltage (Vf) that would otherwise be required to cross the interface between silicon carbide and the Group III nitride in a vertically oriented diode.

FIG. 2 is a side elevational photograph of the diode 10. The resolution of FIG. 2 does not distinguish between epitaxial layers, and accordingly the active portion is designated by the bracketed arrows 15. Similarly, FIG. 2 does not clearly illustrate the contacts 12 and 13.

FIG. 3 is a schematic cross-sectional view oriented generally the same as FIG. 2. It accordingly includes the beveled silicon carbide substrate 14, the active region 15, and the ohmic contacts 12 and 13.

The silicon carbide substrate 14 is substantially transparent. As used herein, a the substrate will be considered transparent when the associated absorptive losses are less than 10%, and more preferably less than 5%. In order to control the transparency, the doping is reduced (or dopants are not even introduced) to an amount that is considered semi-insulating or insulating. The terms semi-insulating and insulating tend to be used qualitatively rather than as exact numbers, but in general a semi-insulating silicon carbide crystal, substrate, or epitaxial layer, will have a net carrier doping of no more than about 7E17 cm⁻³, and will demonstrate a resistivity of at least about 0.10 ohm centimeters (Ω-cm). In exemplary embodiments, the silicon carbide substrate will have a resistivity of at least 0.15 or 0.2 or even 0.3 Ω-cm.

The production of silicon carbide crystals, including crystals having these characteristics, is set forth for example in No. Re34,861 and its parent No. 4,866,005. The production of SiC crystals having semi-insulating characteristics is set forth in Nos. 6,218,680; 6,403,982; 6,396,080; and 6,639,247. The contents of these are incorporated entirely herein by reference. Additionally, transparent silicon carbide can be produced by methods such as those set forth in Nos. 6,200,917; 5,723,391; and 5,762,896; the contents of each of which are also incorporated entirely herein by reference.

The angle of the beveled substrate is indicated by the letter theta (Θ) in FIG. 3 and is selected to minimize internal reflection and thus maximize external quantum efficiency in accordance with well-understood principles of Snell's Law. Accordingly, the angle Θ will be greater than 0° and less than 90° degrees as measured with respect to the interface between the silicon carbide substrate and the Group III nitride active structure, but with angles of between about 45 and 75 being most useful for this purpose. The beveled edge can be produced by etching, saw cutting, laser cutting, or any other conventional technique that does not otherwise interfere with the remaining structure or function of the diode.

FIG. 3 also illustrates the respective epitaxial layers 16 and 17 of Group III nitride materials. Two layers are illustrated consistent with the basic structure of a p-n junction, but it will be understood that additional layers could be included. For example, a higher conductivity p-type layer can be included to enhance the performance of the ohmic contact to the p-type layer, or additional layers can be included for functional purposes such as single or multiple quantum wells or superlattice structures. These are likewise well understood and need not be discussed in detail in order to understand the present invention. As illustrated in FIG. 1, ohmic contact 12 is made to the n-type layer 17, while ohmic contact 13 is made to the p-type layer 16. As schematically illustrated in FIG. 3 and more obvious from FIG. 1, the ohmic contact 13 includes current spreading portions 20 and 21 to enhance its performance on the p-type layer.

By incorporating the transparent silicon carbide substrate 14, the invention provides a substrate which is ideal for light extraction purposes, which also provides the heat-sink advantages of silicon carbide (for example, as compared to sapphire) and better crystal matching properties between the substrate and epitaxial layers (again as typically compared to sapphire).

Perhaps more importantly, the resulting device can be classified as “high brightness,” but can be fabricated much more easily than other high brightness diodes. Although the term “high brightness” is qualitative by nature, it informally refers to diodes that are usefully visible under bright ambient light conditions such as sunlight or well-illuminated indoor environments. More formally, “high brightness” for LEDs such as those described here generally refers to LEDs with a radiant flux of at least 30 mw at 20 mA drive current and preferable more than 35 mw at 20 mA drive current.

As noted in the Background, vertically oriented diodes have certain advantages, but during fabrication they require particular accuracy in front-to-back alignment, a relatively difficult task. In comparison, diodes according to the present invention, (which like many other types of LEDs are typically formed in large numbers on generally circular wafers) have all of their fabrication parts on one face of the wafer rather than two faces. As a result, they can be fabricated more easily than vertical diodes with similar brightness characteristics.

As another advantage, the relatively high brightness can be obtained without using any mirror technology.

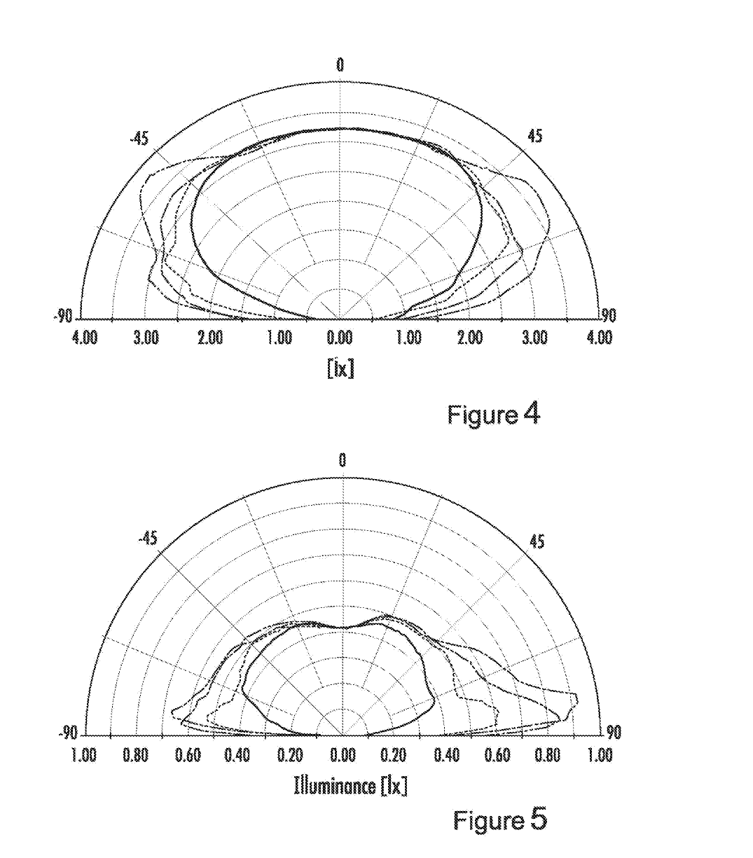

FIGS. 4 and 5 represent far field patterns of light emitting diode chips measured in an integrated sphere (Labsphere, supra at page 11). FIG. 4 represents the far field pattern of a Group III nitride light emitting diode on a sapphire substrate with generally conventional geometry (i.e., a solid rectangle).

FIG. 5 represents the far field pattern of a chip beveled according to the present invention with two topside contacts.

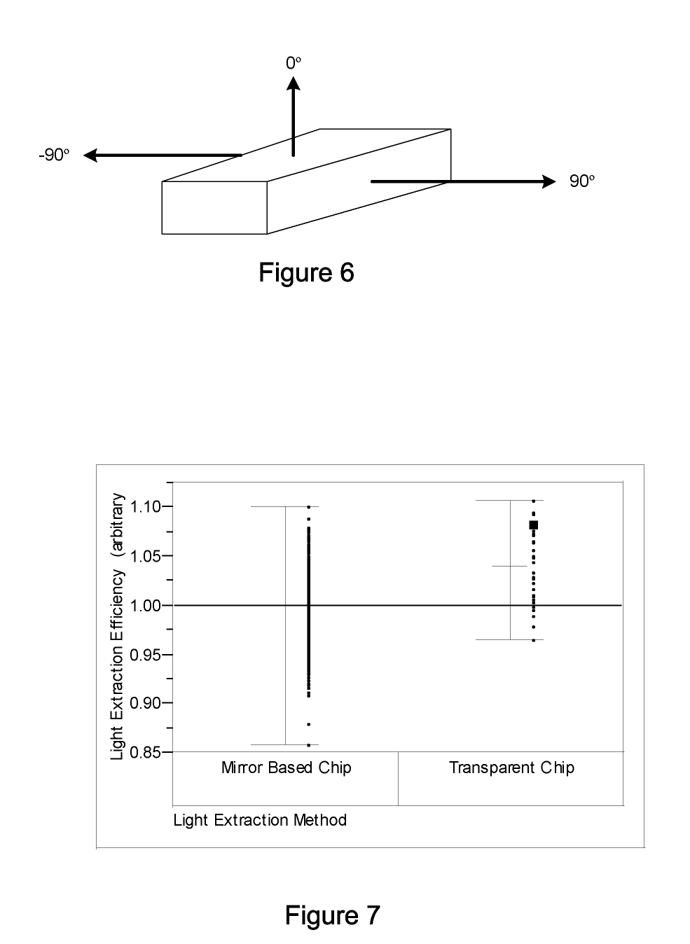

The patterns in FIGS. 4 and 5 respectively include four similar sets of lines. These lines are obtained by scanning each respective chip four times with the chip turned 90° each time with respect to the previous (or other) measurement. This is schematically illustrated in FIG. 6.

In the more conventional sapphire-based chip (FIG. 4) the far field pattern indicates that a relatively similar amount of radiant flux is emitted in all directions. In this chip, the farfield pattern is determined primarily by the transparency of the p-contact material and the dimensions of the chip. However, the dependence of the farfield on these parameters is relatively weak, so the farfield pattern from the sapphire based chip is somewhat fixed to that shown in FIG. 4. This farfield pattern can, of course, be acceptable for certain applications.

In the SiC-based bevel cut chip (FIG. 5), the farfield pattern is determined not only by the parameters described in the preceding paragraph, but also by the length and angle of the bevel. The bevel can be customized to cause the chip to emit relatively more or less light out of the sides of the ship relative to the top of the chip. This can be advantageous in certain applications. The bevel can be further optimized to, for example, emit preferentially more light out of the long dimension of a rectangular-based chip when compared with the light emitted out of the short dimension. This feature of the SiC-based chip is illustrated in FIG. 5. In this case, the performance of the chip is highlighted by significantly greater light extraction from the sides of the diode (towards each respective 90 degree orientation on the chart) rather than perpendicularly from the diode (zero degrees on the chart). This significant extra proportional amount of light emitted from the sides of the diode, particularly when coupled with a phosphor, can provide a favorable increase in converting blue light to white light and a corresponding increase in external output of the fully-packaged LED. Further, the ‘tunable’ far-field characteristic may be achieved without sacrificing the raw output power from the LED chip.

As used herein, the farfield emission toward −90° or 90° in FIG. 4 and FIG. 5 is referred to as the sidelobe emission. In a corresponding manner, the emission toward 0° is referred to as the forward emission.

A typical figure of merit for LEDs is the radiant flux produced at a fixed input current, with 20 mA being an industry standard for LEDs. For a fixed drive current, the radiant flux is primarily determined by 1) epitaxial layer internal quantum efficiency (IQE), 2) chip architecture, and 3) packaging methods. As blue LEDs have become more widely adopted, especially with regard to the production of white light through the incorporation of an appropriate phosphor in the packaging process, the required radiant flux has similarly increased. Further, in order to achieve the higher chip performances, the epitaxial layer growth, chip architectures, and packaging methods have become correspondingly more complicated and demanding. Referring to the chip architecture, this complexity includes the incorporation of mirrors and texturing in the chip design. It is advantageous to maintain a manufacturing process that is as simple as possible since the incorporation of additional light extraction elements such as texturing and mirrors adds cost to the manufacturing process. The chip described here achieves the desired high output powers without the inclusion of cost-adding light extraction elements.

FIG. 7, in which the light extraction efficiencies of two different chip architectures are compared, illustrates this favorable characteristic. For this figure, the IQE of the epitaxial layers and the packaging methods have been held constant so that the relative efficiencies of the light extraction techniques may be compared directly. In this case, the light extraction efficiency of the transparent bevel cut chip on SiC is compared to the light extraction efficiency of a similarly sized chip which uses a mirror as a light extraction enhancing element. As can be seen in the figure, the light extraction efficiency, which is plotted in arbitrary units, is nearly the same for the two different chip geometries. This is especially significant since the chip architecture for the transparent chip does not include a complicated light extraction element such as a mirror.

It should be understood, however, that FIG. 7 is not intended to quantify diodes as “better or worse,” with respect to their performance or purpose, but indicates that chips according to the invention can deliver similar light extraction efficiencies while simplifying manufacturing over other high performing chips. Further, the chips according to the invention do this while providing the opportunity to control output with a phosphor in a manner that improves upon previous versions.

Stated in yet a slightly different context, FIG. 7 shows that diodes according to the invention offer similar or improved light extraction performance in comparison to related, but dissimilar and more complex, diodes. Furthermore, the farfield pattern associated with diodes according to the present invention is adjustable through appropriate chip design including thickness, active area and geometry, and shaping.

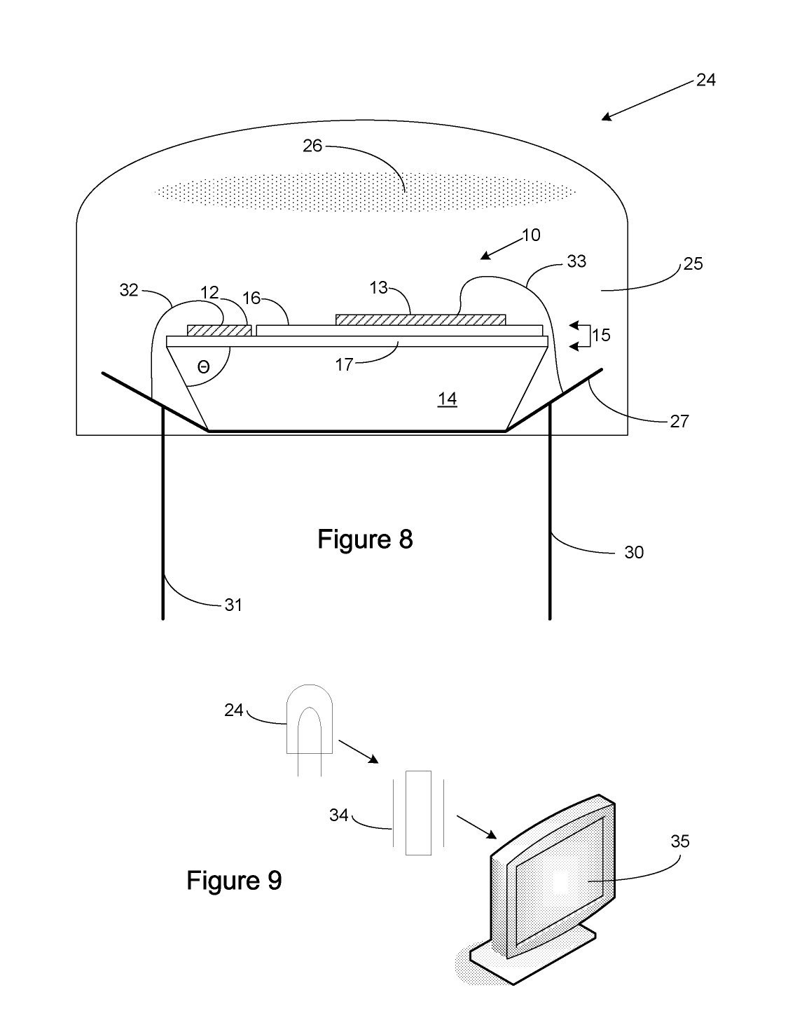

FIG. 8 illustrates the diode 10 in the context of an LED lamp broadly designated at 24. It will be understood that FIG. 8 is schematic and not drawn to scale, and that in particular, the size of the diode 10 is exaggerated in comparison to the overall lamp 24.

In addition to the elements described in the diode with respect to FIG. 3 (which carry the same reference numerals as in FIG. 3), the lamp 24 includes the lens 25 which is typically formed of a polymer. Because of the wavelengths emitted by the diode 10, the lens 25 polymer should be selected to be relatively inert to the emitted light. Certain polysiloxane-based resins (often referred to as “silicone” resins) are appropriate for the lens because they are not nearly as susceptible to photochemical degradation as are some other polymers. In general, and as used herein, the term polysiloxane refers to any polymer constructed on a backbone of —(—Si—O—)ₙ— (typically with organic sidegroups).

The lamp 24 also includes the phosphor illustrated as the dotted ellipse 26. It will again be understood that this is a schematic representation and that the particular position of the phosphor 26 can be tailored for a number of purposes, or in some cases evenly distributed throughout the entire lens 25. A common and widely available yellow conversion phosphor is formed of YAG (yttrium-aluminum-garnet) and when using the silicone-based resins described above, an average particle size of about six microns (the largest dimension across the particle) will be appropriate. Other phosphors can be selected by those of skill in this art without undue experimentation.

The lamp 24 includes a lead frame schematically indicated at 27 with appropriate external leads 30 and 31. The ohmic contact 12 is connected to the external leads 31 by a wire 32 and the ohmic contact 13 is correspondingly connected to the external lead 30 by the corresponding wire 33. Again, these are shown schematically and it will be understood that these elements are positioned in a manner that avoids any short circuit between the ohmic contacts 12,13 the wires 32,33 or the respective external leads 30,31.

FIG. 9 schematically illustrates that the diode 10 or the lamp 24 can also be incorporated into displays. Displays are generally well understood and need not be described herein to inform the skilled person of the advantages of the invention. In some cases, a diode 10 or a lamp 24 according to the invention can be included in the display along with a plurality of respective red and green light emitting diodes to form a full-color display based upon the red, green, and blue emissions.

In other contexts, the phosphor-incorporating lamp 24 according to the invention can be used to generate white light as a backlight for another type of display. One common type of display uses liquid crystal shutters 34 to produce color on an appropriate screen 35 from the white backlighting created by the light emitting diodes.

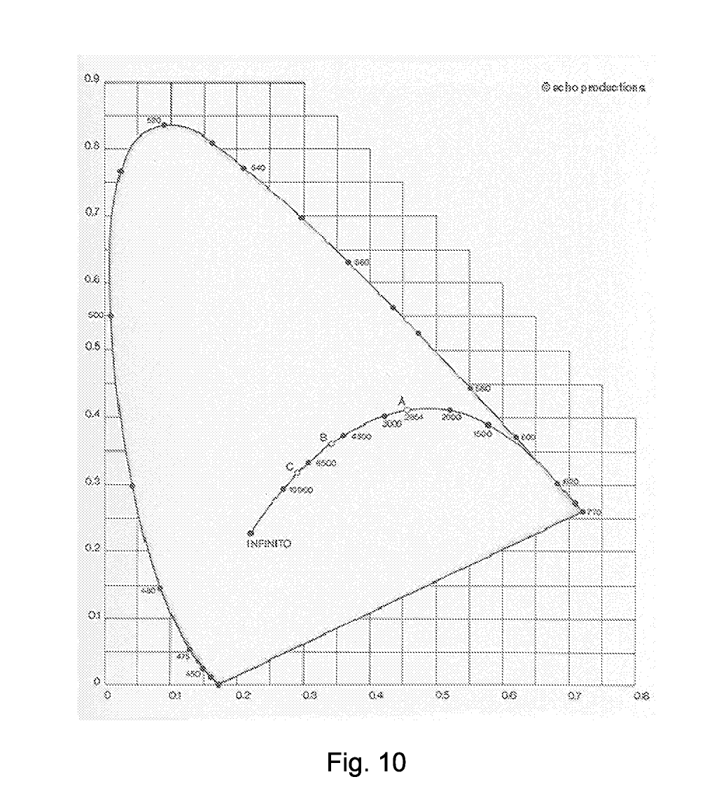

FIG. 10 is one reproduction of the CIE chromaticity diagram marked in wavelength (nanometers) and in the CIE x and y color coordinates, along with the color temperature line. This particular diagram was taken from Echo productions, CIE-1931 System; http://www.colorsystem.com/projekte/engl/37ciee.htm; accessed April 2007. The CIE diagram is, however, widely available from a number of sources and well understood by those of skill in this art. Further background explanation is available in Schubert, supra, at Section 11.4 through 11.8. The nature of light emitting diodes is such that their color output can be expressed as a position on the chart. White light emitting diodes according to the invention can be incorporated in a variety of suitable LED packages including the relatively inefficient ‘sidelooker’ or ‘side emitting’ package; e.g. commonly assigned and copending application Ser. No. 60/745,478 filed Apr. 24, 2006 for “Side-View Surface Mount White LED,” the contents of which are incorporated entirely herein by reference. In this package, light conversion is accompanied by a significant number of light bounces inside of the package, and a photon emitted from the chip may reflect off or pass through the chip one or more times before it exits the package. The white LEDs according to the invention are especially suited to this type of package for two reasons: 1) emitted photons are less likely to be reabsorbed by the chip than they are in similar packages incorporating chips with more absorbing substrates, and 2) the farfield may be adjusted through appropriate chip design and shaping to enhance the white conversion efficiency and light extraction from the package. By using diodes such as those described here in combination with an appropriate phosphor, luminous intensities of greater than 2.0 candela (cd) at 20 mA forward operating current at CIE color coordinates at or near 0.3, 0.3 in a 0.6 mm sidelooker package with an industry standard packaged farfield pattern can be achieved. This also corresponds to a color temperature of about 7000 degrees. In this case, an industry standard farfield may be described as one having a full width at half maximum intensity of greater than 110 degrees. Luminous intensities for higher CIE coordinates, narrower farfields, and wider (e.g. 0.8 mm) packages will be correspondingly higher.

In the drawings and specification there has been set forth a preferred embodiment of the invention, and although specific terms have been employed, they are used in a generic and descriptive sense only and not for purposes of limitation, the scope of the invention being defined in the claims.

1. A light emitting diode comprising:
a transparent silicon carbide substrate;
an active structure formed from the Group III nitride material system on said silicon carbide substrate;
respective ohmic contacts on the top side of said diode; and
said silicon carbide substrate being beveled with respect to the interface between said silicon carbide and said Group III nitride.

2. A diode according to claim 1 wherein said silicon carbide substrate is beveled at an angle of between about 45 and 75 degrees with respect to the interface between said silicon carbide substrate and said Group III nitride active structure.

3. A diode according to claim 1 wherein said transparent silicon carbide substrate is between about 50 and 500 microns thick and is characterized by less than 10 percent absorptive losses.

4. A diode according to claim 3 wherein said transparent silicon carbide substrate is characterized by less than 5 percent absorptive losses.

5. A diode according to claim 1 wherein said substrate is a single crystal having a polytype selected from the group consisting of the 3C, 2H, 4H, 6H, and 15R polytypes of silicon carbide.

6. A diode according to claim 1 wherein said Group III nitride material is selected from the group consisting of gallium nitride, indium gallium nitride, and aluminum indium gallium nitride.

7. A light emitting diode according to claim 1 wherein said active structure is a p-n junction between respective Group III nitride epitaxial layers.

8. A diode according to claim 1 wherein said active structure is selected from the group consisting of single quantum wells, multiple quantum wells, and superlattice structures.

9. A light emitting diode according to claim 1 wherein said active structure includes at least one light emitting layer of indium gallium nitride having the formula InₓGa₁₋ₓN wherein the atomic fraction X of indium is no more than about 0.3.

10. A light emitting diode according to claim 1 wherein said silicon carbide substrate has a resistivity of at least about 0.1 ohm-centimeters.

11. A light emitting diode according to claim 1 wherein said silicon carbide substrate has a resistivity of at least about 0.2 ohm-centimeters.

12. A light emitting diode according to claim 1 wherein said silicon carbide substrate has a resistivity of at least about 0.3 ohm-centimeters.

13. A light emitting diode according to claim 1 wherein:
said active structure is formed from respective p-type and n-type layers of Group III nitride material; and
said ohmic contacts are selected from the group consisting of gold, gold-tin, zinc, gold-zinc, gold-nickel, platinum, nickel, aluminum, ITO, chromium, and combinations thereof.

14. A light emitting diode according to claim 1 having a radiant flux of at least 35 mw at 20 milliamps drive current in an industry standard 5 mm lamp.

15. A light emitting diode according to claim 1 characterized by the far field pattern of FIG. 5

16. A light emitting diode according to claim 1 characterized by a far field pattern in which the sidelobe emission is equal to the forward emission.

17. A light emitting diode according to claim 1 characterized by a far field pattern in which the sidelobe emission is greater than the forward emission.

18. A light emitting diode according to claim 1 that exhibits a far field pattern in which the maximum intensity is at least twice the minimum intensity, and in which the maximum and minimum intensity are between about 60° and 90° degrees from one another.

19. A light emitting diode according to claim 1 that exhibits an output of at least two candela at a 20 milliamp forward operating current at CIE x and y color coordinates of about 0.3 and 0.3.

20. An LED lamp comprising the light emitting diode according to claim 1 packaged with a light converting phosphor.

21. An LED lamp comprising the light emitting diode according to claim 20 packaged with a light converting phosphor in a sidelooker package.

22. An LED lamp according to claim 1 wherein said phosphor comprises YAG.

23. A display comprising a plurality of light emitting diodes according to claim 1.

24. A display according to claim 23 further comprising a plurality of red light emitting diodes and a plurality of green light emitting diodes.

25. A display according to claim 23 further comprising a plurality of white light emitting diodes.

26. A display according to claim 23 wherein said plurality of light emitting diodes backlight a plurality of liquid crystal display shutters.

27. An LED lamp comprising:
a lead frame;
a transparent beveled silicon carbide substrate on said lead frame;
an active structure formed from the Group III nitride material system on said silicon carbide substrate opposite from said lead frame;
respective ohmic contacts on the top side of said diode;
a polymer lens over said substrate and active structure; and
a phosphor distributed in said polymer lens that is responsive to the light emitted by said active structure and that produces a different color of light in response.

28. An LED lamp according to claim 27 wherein:
said active structure emits in the blue portion of the visible spectrum; and
said phosphor absorbs the blue radiation and responsively emits yellow radiation.

29. An LED lamp according to claim 27 wherein said phosphor comprises YAG.

30. A display comprising a plurality of LED lamps according to claim 29.

31. A method of designating the directional output of a light emitting diode comprising beveling a silicon carbide substrate at an acute angle with respect to an interface between the substrate and a Group III nitride epitaxial layer.

32. A method according to claim 31 comprising beveling the silicon carbide substrate to an angle at which the diode has a radiant flux of at least 35 mW at 20 milliamps drive current in an industry standard 5 mm lamp.

33. A method according to claim 31 comprising beveling the silicon carbide substrate to an angle that produces a far field pattern in which the sidelobe emission is equal to the forward emission.

34. A method according to claim 31 comprising beveling the silicon carbide substrate to an angle that produces a far field pattern in which the sidelobe emission is greater than the forward emission.

35. A method according to claim 31 comprising beveling the silicon carbide substrate to an angle that produces at least twice the intensity in directions between 60 degrees and 90 degrees from the direction of minimum intensity.

36. A method according to claim 31 comprising beveling the silicon carbide substrate to an angle that produces an output of at least two candela at a 20 milliamp forward operating current at CIE x and y color coordinates of about 0.3 and 0.3.

37. A method according to claim 31 comprising beveling the silicon carbide substrate to an angle that produces an output of at least two candela at a 20 milliamp forward operating current at CIE x and y color coordinates of about 0.3 and 0.3 in a sidelooker package.

38. A method according to claim 31 comprising beveling the silicon carbide substrate to an angle of between about 45 and 75 degrees with respect to the interface.

39. A light emitting diode comprising:
a silicon carbide substrate that is between about 50 and 500 microns thick and is characterized by less than 10 percent absorptive losses;
an active structure reform from the Group III nitride materials system on said silicon carbide substrate;
respective ohmic contacts on the top side of said diode; and
said silicon carbide substrate having sidewalls substantially perpendicular with respect to the interface between said silicon carbide substrate and said Group III nitride active structure.

40. A light emitting diode according to claim 38 that exhibits an output of at least two candela at a 20 milliamp forward operating current at CIE x and y color coordinates of about 0.3 and 0.3.

41. A light emitting diode according to claim 39 wherein said transparent silicon carbide substrate is characterized by less than 5 percent absorptive losses.

42. A diode according to claim 39 wherein said substrate is a single crystal having a polytype selected from the group consisting of the 3C, 2H, 4H, 6H, and 15R polytypes of silicon carbide.

43. A diode according to claim 39 wherein said Group III nitride material is selected from the group consisting of gallium nitride, indium gallium nitride, and aluminum indium gallium nitride.

44. A light emitting diode according to claim 39 wherein said active structure includes at least one light emitting layer of indium gallium nitride having the formula InₓGa₁₋ₓN wherein the atomic fraction X of indium is no more than about 0.3.

45. A light emitting diode according to claim 39 wherein said silicon carbide substrate has a resistivity of at least about 0.1 ohm-centimeters.

46. A light emitting diode according to claim 39 wherein said silicon carbide substrate has a resistivity of at least about 0.2 ohm-centimeters.

47. A light emitting diode according to claim 39 wherein said silicon carbide substrate has a resistivity of at least about 0.3 ohm-centimeters.

48. A light emitting diode according to claim 39 having a radiant flux of at least 35 mw at 20 milliamps drive current in an industry standard 5 mm lamp.

49. An LED lamp comprising the light emitting diode according to claim 39 packaged with a light converting phosphor.

50. A display comprising a plurality of light emitting diodes according to claim 39.
